(19) United States
(12) Patent Application Publication
(10) Pub. No.: US 2012/0169428 A1
(43) Pub. Date: Jul. 5, 2012

(54) AC COUPLED STACK INDUCTOR FOR VOLTAGE CONTROLLED OSCILLATOR

(75) Inventors: Hassan Maarefi, Irvine, CA (US); Afshin Momtaz, Laguna Hills, CA (US)

(73) Assignee: Broadcom Corporation, Irvine, CA (US)

(21) Appl. No.: 13/094,802

(22) Filed: Apr. 26, 2011

Related U.S. Application Data
(60) Provisional application No. 61/429,016, filed on Dec. 31, 2010.

(51) Int. Cl. H03B 5/12

(52) U.S. Cl. 331/117 FE

(57) ABSTRACT

A voltage controlled oscillator (VCO) may include a stack of a plurality of non-connected inductors that are magnetically and/or electrically through capacitor (AC) coupled to each other and not directly physically connected to each other. The plurality of inductors includes a first inductor connected to a supply voltage and a second inductor connected to a VCO control voltage. The VCO may include a first varactor having a gate coupled to a first terminal of the second inductor to receive the VCO control voltage, a second varactor having a gate coupled to a second terminal of the second inductor to receive the VCO control voltage, and an oscillator sub-circuit coupled to first and second terminals of the first inductor. In one example implementation, the second inductor may contribute to the overall inductance of the inductor stack and provide AC decoupling and/or DC coupling between the VCO control voltage and the varactor(s).

### CROSS-REFERENCE TO RELATED APPLICATIONS

This application claims priority to U.S. Provisional application Ser. No. 61/429,016, filed on 31 Dec. 2010, entitled “AC-Coupled Stack Inductor For Voltage Controlled Oscillator,” hereby incorporated by reference.

### BACKGROUND

Voltage controlled oscillators (VCOs) are commonly used in various communications circuits, and may provide an oscillation signal at a frequency that may be adjusted based on a control voltage. VCOs commonly employ combinations of resistors, capacitors, inductors and transistors. Resistors are relatively cheap in terms of silicon area, but may generate significant unwanted noise, especially at higher temperatures. For example, thermal noise of a resistor may be based upon, or approximated by, the following equation: Resistor Noiseₜₕₑᵣₘₐₗ=4*KTR, where K is Boltzmann's constant, T is temperature, and R is the resistance of the resistor. Inductors offer lower noise, but may consume a relatively large amount of space on an integrated circuit.

### SUMMARY

Various example implementations are disclosed relating to stacked inductors for voltage controlled oscillators (VCOs).

### BRIEF DESCRIPTION OF THE DRAWINGS

FIG. 1 is diagram illustrating a voltage controlled oscillator (VCO) according to an example implementation.

FIG. 2 is a diagram illustrating the operation of a varactor according to an example implementation.

FIG. 3 is a flow chart illustrating operation of at least a portion of a voltage controlled oscillator (VCO) circuit to provide an oscillator signal according to an example implementation.

### DETAILED DESCRIPTION

According to an example implementation, VCO 110 may include an oscillator sub-circuit 113, one or more varactors, such as varactors 112, 114 (or other variable capacitance devices), capacitors C1 and/or C2, and an alternating current (AC)-coupled stacked inductor 111. The capacitance of each of varactors 112, 114 may vary based on an input voltage applied to the varactors.

Oscillator sub-circuit 113 may include, for example, two cross-coupled transistors T1 and T2. In this example, T1 and T2 may be cross-coupled to provide positive feedback to each transistor T1 and T2, such that the oscillator sub-circuit 113 will oscillate and output an oscillation (or oscillator) signal. In one example implementation, the oscillator sub-circuit 113 is a differential circuit where the output includes a positive output (Voutp) and a negative output (Voutn), where the output voltage may be determined as Voutp−Voutn, for example. While sub-circuit 113 is a differential circuit, a single ended circuit may also be used that produces a single output signal (e.g., where a voltage of a single output signal is measured with respect to ground). The output of the VCO 110 may also be the Voutp and Voutn, with the total output voltage (e.g., for a differential circuit) being Voutp−Voutn.

In an example implementation, a supply voltage Vdd is received by (or supplied to) a node 131 of inductor L1. Inductor L1 provides direct current (DC) coupling and AC decoupling. DC coupling means that a DC or substantially DC signal or voltage is passed between different portions of inductor L1. AC decoupling means that an AC (e.g., signal having a non-zero frequency) signal or voltage input to one point of the inductor L1 is not typically passed and output to another point (e.g., opposite node or terminal) of the inductor L1. Thus, for signals having a high enough frequency (AC signals), inductor L1 may operate or appear as an open circuit (or substantially open circuit), and thus, inductor L1 performs AC decoupling.

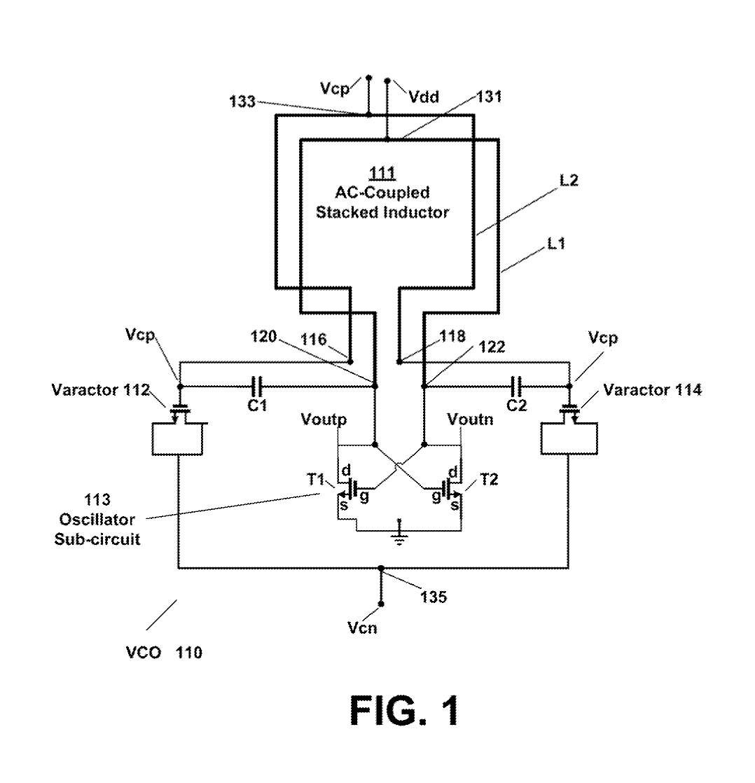

Therefore, the supply voltage Vdd (at DC or a frequency of 0 Hz) applied to node 131 is also applied to the terminals 120 and 122 of L1, via the DC coupling of inductor L1. Thus, the supply voltage Vdd is applied to the gates (g) of transistors T1 and T2. The gate of transistor T1 is connected to the drain (d) of transistor T2, and the gate of transistor T2 is connected to the drain (d) of transistor T1, in a cross-coupled arrangement, as shown in FIG. 1. The sources (s) of transistors T1 and T2 are connected to ground.

VCO 110, which may be considered to include an LC oscillator, may oscillate a reference frequency determined, at least in part, by the overall inductance (including L1, L2) and the overall capacitance of the circuit (including values of C1 and C2, and varactors 112, 114). Thus, for example, the oscillation frequency of VCO 110 may be varied by changing the capacitance values for varactors 112, 114. The capacitance of varactors 112, 114 may be changed by varying the control voltage applied to the varactors. Note that other capacitors and inductors may be provided within VCO 110, although not shown. In an example operation of the VCO 110, if ideal inductors and capacitors are provided, a charge on one or both capacitors (C1, C2, varactors 112, 114, or other capacitor) provides a charge imbalance on the plates of the capacitor(s) (e.g., C1, C2, varactors 112, 114), which may cause current to flow. Once current is flowing, during a first half of an oscillation cycle, the inductors L1, L2 may absorb the energy from such current and store the energy temporarily as a magnetic field on the inductors L1, L2. During a second half of the oscillation cycle, the energy discharges from inductors L1, L2, and this energy is stored as charge on the plates of capacitors C1 and/or C2, and/or varactors 112, 114 (energy stored as an electric field on one or more capacitors of VCO 110). This oscillation cycle may repeat, with energy flowing alternately between the inductors (e.g., L1, L2, with energy stored as a magnetic field) and the capacitors (e.g., energy stored on capacitors as an electric field) of VCO 110.

the components within VCO 110 may be considered non-ideal, that is, the components, such as L1, L2, C1, C2, varactors 112, 114, etc. (and others) may introduce losses into VCO 110. These losses may, without additional circuits, cause the amplitude of the oscillating energy to decrease over time or dissipate. Therefore, oscillator sub-circuit 113, including transistors T1 and T2 may be used to provide positive feedback for the oscillating operation of VCO 110.

The following describes an example of how the transistors T1 and T2 may operate to provide positive feedback to output an oscillation signal as signals Voutp and Voutn. A small signal may appear on the gate of transistor T1 which may cause transistor T1 to turn on (e.g., when the gate voltage of T1 exceeds Vt or threshold voltage of T1). When transistor T1 turns on, the drain of T1 is pulled to ground (or low). Based on the connection between the drain of T1 and the gate of T2, this causes the gate of transistor T2 to go low (or to ground), which causes T2 to turn off, which allows Voutp (and drain of T1) to increase in voltage. The increased voltage on the Voutp is applied to the gate of transistor T2, which causes T2 to turn on, which causes Voutn to go low or to ground. In this manner, transistors T1 and T2 may turn on and off in an alternating fashion to generate output signals Voutp and Voutn that oscillate between a high voltage and a low voltage. This provides an example implementation and example operation of an illustrative oscillator sub-circuit 113, and other types of oscillation sub-circuits may be used.

The VCO 110 includes an AC-coupled stacked inductor 111 that may include multiple (or a plurality of) non-connected inductors that are AC-coupled to each other (or coupled via magnetic field and/or electric field that occurs between the inductors, or is generated by the inductors, when an AC signal is present on the inductor(s)), but are not directly physically connected to each other (e.g., not DC-coupled to each other), according to one example implementation. Thus, in this example implementation, the plurality of inductors of stacked inductor 111 may be described as being AC-coupled or magnetically coupled to each other, but are not directly physically connected to each other. Stacked inductor 111 may include, for example, a plurality of inductors (e.g., provided in parallel) including at least inductor L1 and inductor L2, although more inductors may be included. Two inductors are provided by way of example. According to an example implementation, inductor L1 is connected to a supply voltage at node 131, and inductor L2 is connected to a VCO control voltage (Vcp) at node 133.

According to an example implementation, inductors L1 and L2 may be differential single turn inductors. Each inductor, L1 and L2, may include two terminals. Inductor L1 includes terminals 120 and 122, while inductor L2 includes terminals 116 and 118.

Inductors L1 and L2 include an impedance that its magnitude may be described as wL, where w (omega) is signal frequency and L is the inductance. Therefore, at DC (w=0 or very low frequency), impedance of an inductor (inductors L1 and L2) is very low or zero. Whereas, for signal frequencies that are higher (e.g., AC signals), the impedance of the inductor may be significant and increases as the signal frequency (w) increases. Therefore, as noted, inductors L1 and L2 may provide DC coupling (providing a short circuit for DC voltages or voltages at zero frequency), and provides AC decoupling (for signal frequencies greater than zero), for example. Thus, an inductor, such as inductors L1 and L2 may typically appear as an open (or substantially open) circuit (or provide decoupling between two points) for signals having non-zero frequencies (depending on the frequency), for example. Therefore, inductors L1 and L2 may be described as providing DC coupling and AC decoupling.

Terminals 120 and 122 are connected to drains of transistors T1 and T2, respectively (and also connected to output terminals that output Voutp and Voutn, respectively). As noted, inductor L1 provides DC coupling (e.g., providing approximately zero impedance or very low impedance for signals at DC or a frequency of zero Hertz, or very low frequency). Thus, the DC supply voltage (Vdd) provided at node 131 of inductor L1 also is provided at terminals 120 and 122, based on the DC coupling of inductor L1. This inputs supply voltage as DC input to the gates of transistors T1 and T2, thereby providing a bias voltage and bias current for the transistors T1 and T2 of the oscillator sub-circuit 113.

Terminals 116 and 118 of inductor L2 are connected to inputs (terminals or gates) of varactors 112 and 114, respectively. Varactors 112 and 114 are variable capacitance devices where the capacitance of the varactor changes or varies based on the control voltage applied to the gate of the varactor. The positive control voltage Vcp is applied to the node 133 of inductor L2. By virtue of the DC coupling of inductor L2, the positive control voltage Vcp is also input to (or received at) nodes 116 and 118. This causes the positive control voltage Vcp to be input to the gates of varactors 112 and 114. Also, the source and drain of varactor 112 are connected together, and connected to a negative control voltage Vcn. The source and drain of varactor 114 are connected together, and connected to the negative control voltage Vcn. In this case, the example varactors 112 and 114 are differential devices, and the capacitance of each of varactors 112 and 114 varies based on the overall control voltage, Vcp−Vcn, applied to the varactors 112 and 114.

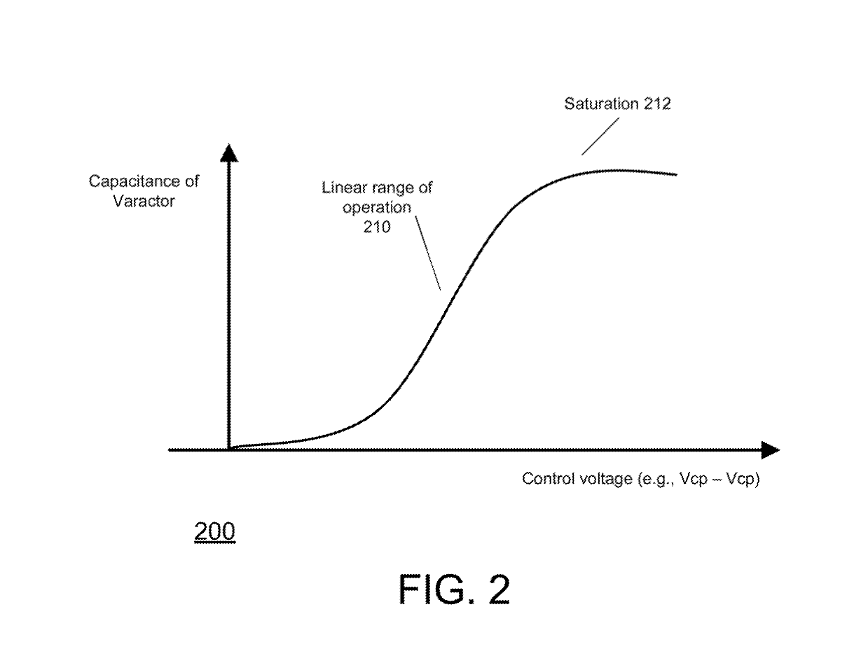

FIG. 2 is a diagram 200 that illustrates the operation of a varactor (such as a varactors 112 or 114) according to an example implementation. The varactor may be considered a variable capacitance device. The capacitance of the varactor may vary based on the voltage (control voltage) applied to the input terminal or gate of the varactor. In diagram 200, the X axis represents the amount of control voltage applied to the input terminal (e.g., gate) of the varactor. For a differential varactor, the control voltage may be represented, for example, as Vcp−Vcn, or Vcn−Vcp. The Y axis on diagram 200 represents capacitance of the varactor which changes based on the applied control voltage. After an initial flat area, the operation of the varactor enters a substantially linear range 210 of operation, for example, where the capacitance generally increases as the control voltage increases, although this is merely illustrative, and not all varactors operate in this fashion. At some point, as the control voltage increases, the varactor may become saturated, and enter a saturation region 212 where the capacitance of the varactor may not increase very much even as the applied control voltage (e.g., Vcp−Vcn) is increased further. The varactor operation illustrated in FIG. 2 is provided as an example or illustrative operation, and the description is not limited thereto. Other varactor circuits and other varactor operations may be used as well.

In addition, a capacitor C1 has a first node connected to terminal 120 of inductor L1 and a second node connected to both the gate of varactor 112 and node 116 of inductor L2. Similarly, since the VCO 110 is differential, a capacitor C2 has a first node connected to terminal 122 of inductor L1 and a second node connected to both the gate of varactor 114 and terminal 118 of inductor L2. Capacitors C1 and C2 each provide DC decoupling and AC coupling between their respective nodes (or ends).

As noted, the AC-coupled stacked inductor 111 includes a plurality of stacked inductors, including L1 and L2. The stacked inductors (e.g., L1, L2) are AC-coupled due to the presence of a magnetic field that occurs between these plurality of inductors when a voltage is applied to the inductors. Thus, the inductors L1, L2 (and others within stacked inductor 111) are AC-coupled or magnetically-coupled. Therefore, based on this AC (or magnetic) coupling between inductors L1 and L2, the plurality of inductors of the stacked inductor 111 provide a combined or total inductance for VCO for AC (or non-zero) frequencies, such as for the oscillation signal output by the VCO (Voutp, Voutn). Therefore, in this example, all of the inductors (including L1 and L2) contribute to the overall inductance of the stacked inductor for the VCO 110. As noted, the oscillation frequency of the oscillation signal (Voutp, Voutn) output by the VCO 111 is at least in part based on the overall or combined inductance of the AC-coupled stacked inductor 111. Due to the AC coupling (or magnetic coupling) between the inductors L1 and L2, both L1 and L2 contribute to the oscillation frequency, even though only inductor L1 is directly connected to the gates of the transistors T1, and T2 of oscillator sub-circuit 113.

In an example implementation, physical inductors (including L1, L2) of the stacked inductor 111 are not directly connected to each other. Thus, according to an example embodiment, there are no vias or other conductors provided to directly physically connect together the multiple inductors (or inductor layers) of stacked inductor 111. However, the inductors of the stacked inductor including L1 and L2 are coupled via a magnetic field. Thus, these inductors L1 and L2 are AC coupled, but are not DC coupled, according to an example implementation. This allows an efficient usage of the inductors L1 and L2, since different DC voltages may be applied to each of inductors L1 and L2 (since no DC coupling between inductors L1, L2), while still allowing the group of inductors L1, L2 to operate or function as a single inductance for the VCO with respect to AC signals (due to AC coupling between L1, L2).

For example, as shown in FIG. 1, inductor L1 operates or functions to provide a DC coupling or DC connection to distribute or provide the supply voltage Vdd to the gates of the transistors T1 and T2, e.g., where Vdd provides a supply voltage (or bias voltage) and provides a bias current to the transistors T1, T2. Inductor L1 also contributes to the overall or combined inductance of the stacked inductor 111 for VCO 110 for AC signals (such as the oscillation signal).

Similarly, as shown in FIG. 1, inductor L2 operates or functions to provide a DC coupling or DC connection to distribute the VCO control voltage (Vcp) to the inputs or gates of the varactors 112 and 114. Also, the inductor L2 provides AC decoupling between the control voltage Vcp and the gates of varactors 112 and 114. Inductor L2 also provides AC decoupling between positive and negative control voltages (Vcp and Vcn), which allows the voltage of the oscillation signal (Voutp, Voutn) to remain at a high voltage level, which may keep phase nose relatively low. Therefore, for nonzero frequencies of operation for transistors T1 and T1 (and VCO 110 in general), the AC decoupling of L2 between Vcp and Vcn may operate to maintain the output signal (Voutp−Voutn) and reduce phase noise. Inductor L2 also contributes to the overall inductance of the stacked inductor 111 for the operation of the VCO, e.g., for AC signals.

AC decoupling may be implemented using a resistor, which is cheaper (or requires less space) than an inductor, but a resistor generates more noise (e.g., more thermal noise) than an inductor. According to an example implementation, by not providing any direct physical connections between inductors L1 and L2, this allows L2 to be used for two operations or functions, including 1) contributing to the overall inductance of the stacked inductor 111 for the VCO, and 2) providing AC decoupling between control voltage Vcp and varactors 112, 114. This technique (including not using vias or direct physical connections between L1 and L2, and using inductor L2 for two functions or operations) therefore, may allow inductors to be used for AC decoupling (instead of resistors, which generate more noise), and thus decrease noise, and allows one inductor to be used for two functions or operations, thereby saving cost and/or space on an integrated circuit. Therefore, advantages of these techniques may include reduced noise (e.g., since an inductor may be used for AC decoupling rather than a resistor) and reduced cost/space (since one inductor, e.g., inductor L2, may be used for two functions or operations, which may eliminate the need for separate devices (resistors or inductors) for these functions or operations).

According to an example embodiment, a voltage controlled oscillator (VCO) may be provided that includes a stack of a plurality of non-connected inductors that are magnetically coupled to each other and not directly physically connected to each other, the plurality of inductors including at least a first inductor connected to a supply voltage and a second inductor connected to a VCO control voltage. The VCO may include a first varactor having a gate coupled to a first terminal of the second inductor to receive the VCO control voltage, a second varactor having a gate coupled to a second terminal of the second inductor to receive the VCO control voltage, and an oscillator sub-circuit coupled to first and second terminals of the first inductor.

In an example implementation, the first and second inductors may be provided as a stack of single-turn inductors. Also, the VCO may be a single ended VCO or a differential circuit.

In an example implementation, the VCO may include a first capacitor coupled between the first terminal of the first inductor and the first terminal of the second inductor and a second capacitor coupled between the second terminal of the first inductor and the second terminal of the second inductor.

Also, the oscillator sub-circuit may include two cross-coupled transistors. In one example implementation, the VCO may include a first transistor having a gate coupled to the second terminal of the first inductor, and a second transistor having a gate coupled to the first terminal of the first inductor. A gate of the first transistor may be coupled to a first source/drain terminal of the second transistor, and a gate of the second transistor may be coupled to a first source/drain terminal of the first transistor.

In an example implementation, the second inductor may provide a resistor-less alternating current (AC) decoupling and direct current (DC) coupling between the VCO control voltage and the one or more varactors.

In an example implementation, the second inductor may perform at least two functions including contributing to the overall or combined inductance of the stack of a plurality of non-connected inductors for the VCO, and providing an AC decoupling and direct current (DC) coupling between the VCO control voltage and the first and second varactors.

According to another example implementation, a circuit is provided for use in a voltage controlled oscillator (VCO). The circuit includes an alternating current (AC)-coupled stacked inductor including at least: a first inductor and a second inductor. The first and second inductors are magnetically connected and not directly physically connected to each other, wherein the first and second inductors provide an inductor for the VCO, wherein an oscillation frequency of the VCO is based, at least in part, upon the combined inductance of the first and second inductors. The first inductor is coupled to a supply voltage and to an oscillator sub-circuit of the circuit. The second inductor is connected to a first VCO control voltage and to one or more varactors, the second inductor providing a resistor-less AC decoupling between the first VCO control voltage and the one or more varactors.

In an example implementation, the second inductor provides AC decoupling between the first VCO control voltage and a second VCO control voltage for a differential VCO. In an example implementation, the AC-coupled stacked inductor includes a plurality of differential single loop inductors that are magnetically coupled. The circuit may include one or more capacitors, wherein the first inductor and the second inductor are coupled together via the one or more of the capacitors.

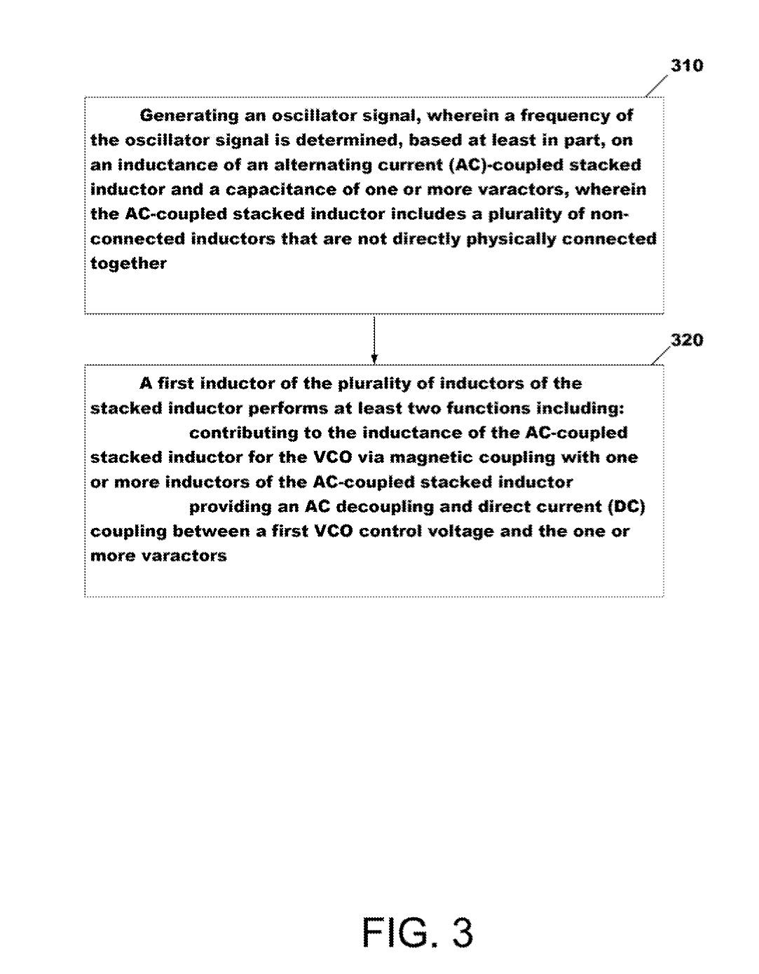

FIG. 3 is a flow chart illustrating operation of at least a portion of a voltage controlled oscillator (VCO) circuit to provide an oscillator signal according to an example implementation. Operation 310 may include generating an oscillator signal, wherein a frequency of the oscillator signal is determined, based at least in part, on an inductance of an alternating current (AC)-coupled stacked inductor and a capacitance of one or more varactors. The AC-coupled stacked inductor includes a plurality of non-connected inductors that are not directly physically connected together. At operation 320, a first inductor of the plurality of inductors of the stacked inductor performs at least two functions including: contributing to the inductance of the AC-coupled stacked inductor for the VCO via magnetic coupling with one or more inductors of the AC-coupled stacked inductor, and providing an AC decoupling and direct current (DC) coupling between a first VCO control voltage and the one or more varactors.

In an example implementation of the method of FIG. 3, at least the first inductor and a second inductor of the stacked inductor are coupled together via one or more capacitors.

While certain features of the described implementations have been illustrated as described herein, many modifications, substitutions, changes and equivalents will now occur to those skilled in the art. It is, therefore, to be understood that the appended claims are intended to cover all such modifications and changes as fall within the true spirit of the various embodiments.

What is claimed is:

1. A voltage controlled oscillator (VCO) comprising:
a stack of a plurality of non-connected inductors that are magnetically coupled to each other and not directly physically connected to each other, the plurality of inductors including at least a first inductor connected to a supply voltage and a second inductor connected to a VCO control voltage;
a first varactor having a terminal coupled to a first terminal of the second inductor to receive the VCO control voltage;
a second varactor having a terminal coupled to a second terminal of the second inductor to receive the VCO control voltage; and
an oscillator sub-circuit coupled to first and second terminals of the first inductor.

2. The VCO of claim 1 wherein the first and second inductors are provided as a stack of single-turn inductors.

3. The VCO of claim 1 wherein the VCO comprises a differential circuit.

4. The VCO of claim 1 and further comprising:
a first capacitor coupled between the first terminal of the first inductor and the first terminal of the second inductor;
a second capacitor coupled between the second terminal of the first inductor and the second terminal of the second inductor.

5. The VCO of claim 1 wherein the oscillator sub-circuit comprises two cross-coupled transistors.

6. The VCO of claim 1 wherein the oscillator sub-circuit comprises:
a first transistor having a gate coupled to the second terminal of the first inductor; and
a second transistor having a gate coupled to the first terminal of the first inductor; and
wherein a gate of the first transistor is coupled to a first source/drain terminal of the second transistor, and wherein a gate of the second transistor is coupled to a first source/drain terminal of the first transistor.

7. The VCO of claim 1 wherein the second inductor provides a resistor-less alternating current (AC) decoupling and direct current (DC) coupling between the VCO control voltage and the one or more varactors.

8. The VCO of claim 1 wherein the second inductor is configured to:
contribute to the overall or combined inductance of the stack of a plurality of non-connected inductors for the VCO;
provide an AC decoupling and direct current (DC) coupling between the VCO control voltage and the first and second varactors.

9. A circuit for use in a voltage controlled oscillator (VCO), the circuit comprising:
an alternating current (AC)-coupled stacked inductor including at least:
a first inductor and a second inductor, the first and second inductors being magnetically connected and not directly physically connected to each other, wherein the first and second inductors provide an inductor for the VCO, wherein an oscillation frequency of the VCO is based, at least in part, upon the combined inductance of the first and second inductors;
wherein the first inductor is coupled to a supply voltage and to an oscillator sub-circuit of the circuit; and
wherein the second inductor is connected to a first VCO control voltage and to one or more varactors, the second inductor providing a resistor-less AC decoupling between the first VCO control voltage and the one or more varactors.

10. The circuit of claim 9 wherein the second inductor provides AC decoupling between the first VCO control voltage and a second VCO control voltage for a differential VCO.

11. The circuit of claim 9 wherein the AC-coupled stacked inductor comprises plurality of differential single loop inductors that are magnetically coupled.

12. The circuit of claim 9 and further comprising one or more capacitors, wherein the first inductor and the second inductor are coupled together via the one or more capacitors.

13. A method of providing an oscillator signal from a voltage controlled oscillator (VCO) comprising:
generating an oscillator signal, wherein a frequency of the oscillator signal is determined, based at least in part, on an inductance of an alternating current (AC)-coupled stacked inductor and a capacitance of one or more varactors;
wherein the AC-coupled stacked inductor includes a plurality of non-connected inductors that are not directly physically connected together;
wherein a first inductor of the plurality of inductors of the stacked inductor performs at least two functions including:
contributing to the inductance of the AC-coupled stacked inductor for the VCO via magnetic coupling with one or more inductors of the AC-coupled stacked inductor;
providing an AC decoupling and direct current (DC) coupling between a first VCO control voltage and the one or more varactors.

14. The method of claim 13 wherein at least the first inductor and a second inductor of the stacked inductor are coupled together via one or more capacitors.
